(19) United States
(12) Patent Application Publication
(10) Pub. No.: US 2026/0266899 A1
(43) Pub. Date: Sep. 10, 2026

(54) TEST TOOL

(71) Applicant: Elite Semiconductor Microelectronics Technology Inc., Hsinchu (TW)

(72) Inventor: Ya-Ting Chung, Hsinchu (TW)

(73) Assignee: Elite Semiconductor Microelectronics Technology Inc., Hsinchu (TW)

(21) Appl. No.: 19/207,316

(22) Filed: May 13, 2025

(30) Foreign Application Priority Data
Mar. 4, 2025 (TW) 114107857

(51) Int. Cl. G01R 31/28

(52) U.S. Cl. CPC G01R 31/2896

(57) ABSTRACT

A test tool is used to position a chip on a test circuit board and includes a positioning base and a pressing member. The test circuit board has a plurality of contacts and a probe base with a plurality of probes. The positioning base has a hole for accommodating the chip. The positioning base is positioned on the test circuit board and receives the probe base to make the probes contained in the hole to be connected to the pins and aligned with the contacts. A wall of the hole is formed with two engaging grooves opposite to each other. An engaging end portion of each elastic arm of the pressing member forms a hook protruding toward the engaging groove and presses the chip when the hook is engaged with the engaging groove, for connecting pins of the chip to the contacts via the probes.

### BACKGROUND OF THE INVENTION

### 1. Field of the Invention

The present invention relates to a test tool, and more specifically, to a test tool for positioning a chip to be electrically connected to a test circuit board.

### 2. Description of the Prior Art

In general, after a chip is packaged, the chip must be placed in a receiving groove of a test tool and an upper cover of the test tool must be pressed down to electrically connect the chip to a test circuit board for subsequent chip testing. Therefore, the structural design of the test tool is often too complicated, thereby increasing the manufacturing cost of the test tool and affecting the operational convenience of the test tool. In addition, since most test circuit boards do not have screw holes for the test tool to be directly screwed, it is necessary to additionally dispose alignment blocks and a carrier on the test circuit board to fix the receiving groove of the test tool and the upper cover to the test circuit board via a large number of screws or metal fasteners. This will result in a time-consuming and strenuous tool positioning process, so as to greatly increase the chip testing time and cost.

### SUMMARY OF THE INVENTION

Thus, one purpose of the present invention is to provide a test tool for positioning a chip to be electrically connected to a test circuit board, for solving the aforesaid problems.

According to one embodiment, a test tool of the present invention is suitable for positioning a chip to be coupled to a test circuit board. The chip has a plurality of pins, the test circuit board has a plurality of contacts and a probe base with a plurality of probes, and the test tool includes a positioning base and a pressing member. The positioning base has a hole for accommodating the chip. The positioning base is positioned on the test circuit board and receives the probe base to make the plurality of probes contained in the hole to be connected to the plurality of pins and aligned with the plurality of contacts, and a wall of the hole forms two engaging grooves opposite to each other. The pressing member has two elastic arms. An engaging end portion of each elastic arm forms a hook protruding toward the engaging groove and presses the chip when the pressing member is pressed into the hole to make the hook engaged with the engaging groove, for electrically connecting the plurality of pins to the plurality of contacts via the plurality of probes.

In summary, the test tool provided by the present invention utilizes the positioning base to receive the probe base for making the probes of the probe base coupled to the pins of the chip and aligned with the contacts of the test circuit board. Next, after the pressing member is engaged with the hole and presses the chip downward, the chip can be electrically connected to the test circuit board via the probe base. In such a manner, via the aforesaid simple pressing operation, the electrical connection between the chip and the test circuit board can be quickly and easily completed, so as to effectively solve the prior art problem that the test tool design is too complicated to increase the tool manufacturing cost and cause difficulties in operating the test tool, thereby greatly improving the operating convenience of the test tool.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a top view of a test tool mounted on a test circuit board according to an embodiment of the present invention.

FIG. 2 is an exploded diagram of the test tool in FIG. 1.

FIG. 3 is a cross-sectional diagram of the test tool in FIG. 1 along a cross-sectional line A-A.

FIG. 4 is a partially-enlarged diagram of a pressing member in FIG. 2.

FIG. 5 is a partially-enlarged diagram of a positioning base in FIG. 2.

FIG. 6 is a partially-enlarged diagram of a first positioning block structure in FIG. 2.

FIG. 7 is a top view of a test tool mounted on the test circuit board according to another embodiment of the present invention.

FIG. 8 is a top view of a test tool mounted on the test circuit board according to another embodiment of the present invention.

FIG. 9 is a cross-sectional diagram of a test tool according to another embodiment of the present invention.

### DETAILED DESCRIPTION

The present invention will now be described more specifically with reference to the following embodiments and the accompanying drawings. Other advantages and effects of the present invention can be easily understood by a person ordinarily skilled in the art in view of the detailed descriptions and the accompanying drawings. The present invention can be implemented or applied to other different embodiments. Certain aspects of the present invention are not limited by the particular details of the examples illustrated herein. Without departing from the spirit and scope of the present invention, the present invention will have other modifications and changes. It should be understood that the appended drawings are not necessarily drawn to the scale and configuration of each component (e.g., structural scales and arrangement of a test tool, a chip, a test circuit board, protruding electronic components and a probe base) in the drawings is merely illustrative, not presenting an actual condition of the embodiments.

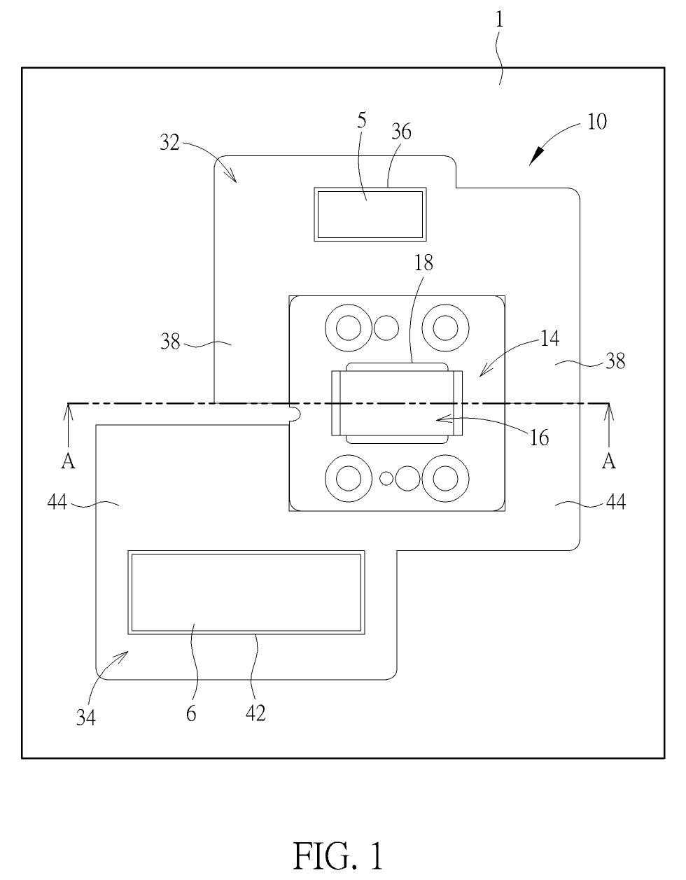

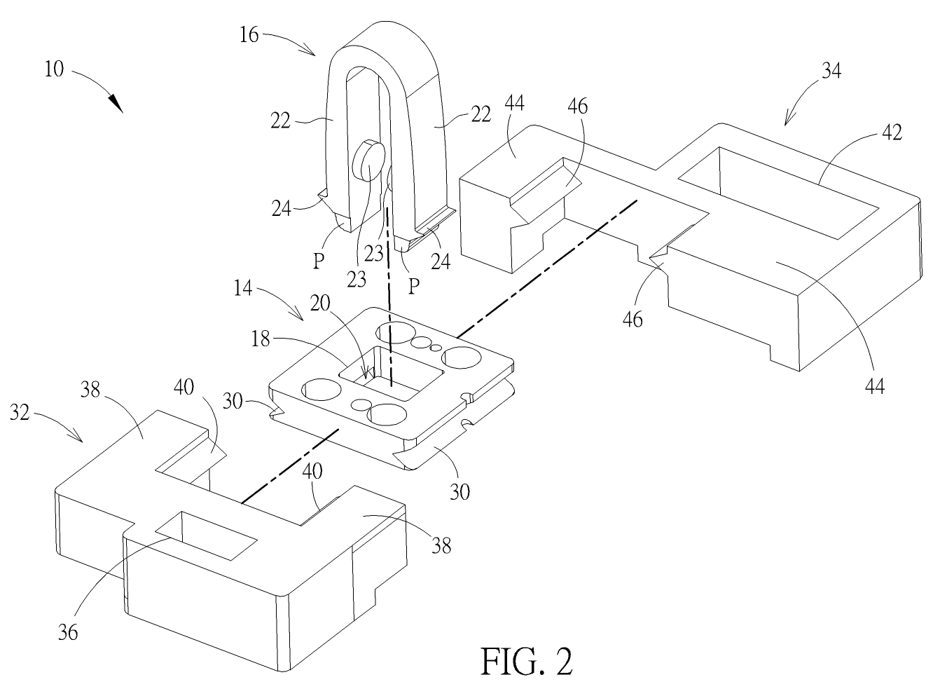

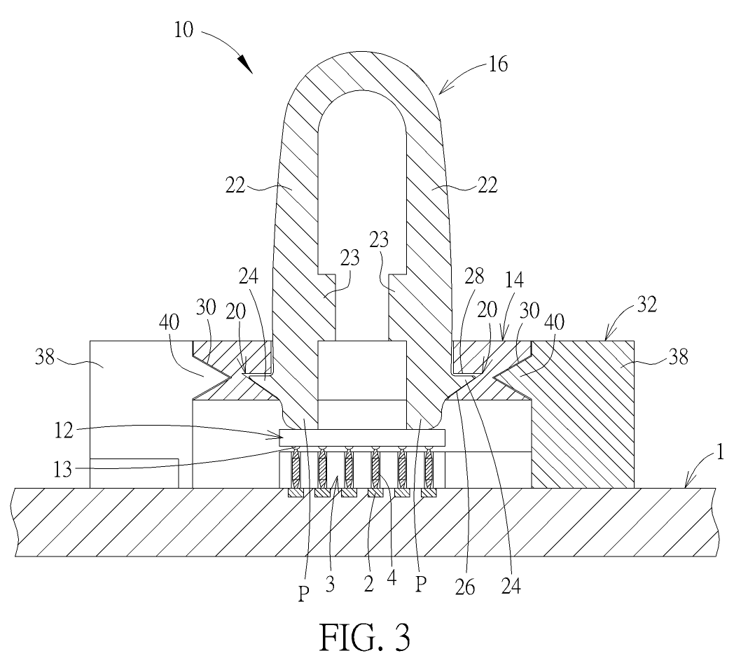

Please refer to FIGS. 1, 2 and 3. FIG. 1 is a top view of a test tool 10 mounted on a test circuit board 1 according to an embodiment of the present invention. FIG. 2 is an exploded diagram of the test tool 10 in FIG. 1. FIG. 3 is a cross-sectional diagram of the test tool 10 in FIG. 1 along a cross-sectional line A-A. For clearly showing the structural design of the test tool 10, the test circuit board 1 and protruding electronic components mounted thereon are only depicted by simple lines. As for the related description of the test circuit design and the electronic component configuration of the test circuit board 1, it is commonly seen in the prior art and omitted herein.

As shown in FIGS. 1-3, the test tool 10 could be suitable for testing a packaged semiconductor chip (as shown in FIG. 3, a chip 12 is positioned and electrically connected to a test circuit board 1 for subsequent chip testing). The chip 12 could have a plurality of pins 13, and the test circuit board 1 could have a plurality of contacts 2 and a probe base 3. The probe base 3 has a plurality of probes 4 to serve as a bridge conduction device for electrical connection between the plurality of pins 13 of the chip 12 and the plurality of contacts 2 of the test circuit board 1.

The test tool 10 includes a positioning base 14 and a pressing member 16. The positioning base 14 has a hole 18 to accommodate the chip 12. The positioning base 14 is positioned on the test circuit board 1 and receives the probe base 3, so that the plurality of probes 4 can be accommodated in the hole 18 to be connected to the plurality of pins 13 of the chip 12 and aligned with the plurality of contacts 2. A wall of the hole 18 is formed with two engaging grooves 20 opposite to each other. The pressing member 16 could be preferably in an inverted-U shape (but not limited thereto) and has two elastic arms 22. An engaging end portion P of each elastic arm 22 protrudes toward the engaging groove 20 to form a hook 24. As such, when a user applies force to clamp the pressing member 16 for pressing the pressed and narrowed pressing member 16 into the hole 18, the hook 24 of each elastic arm 22 is aligned with the engaging groove 20 in the hole 18. Next, when the pressing member 16 is released, the elastic arm 22 of the pressing member 16 can elastically return to its original position to make the hook 24 engaged with the engaging groove 20, and the engaging end portion P of the elastic arm 22 can correspondingly press the chip 12 downward, thereby electrically connecting the plurality of pins 13 to the plurality of contacts 2 via the plurality of probes 4 (as shown in FIG. 3) for subsequent chip testing.

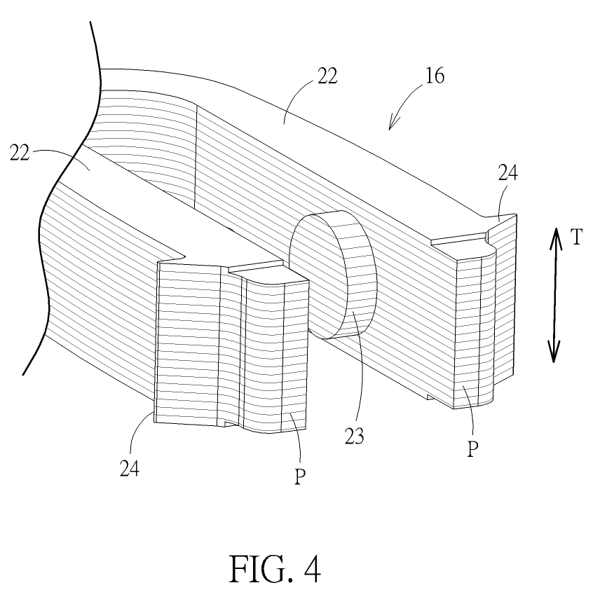

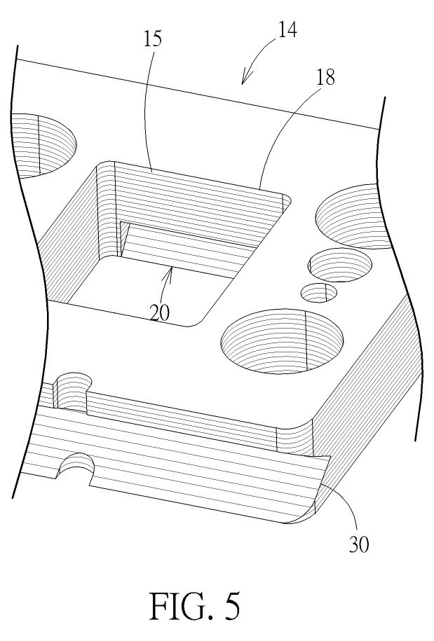

To be more specific, the present invention could preferably adopt a 3D printing process (the related description is commonly seen in the prior art and omitted herein) to manufacture the positioning base 14 and the pressing member 16. For example, please refer to FIGS. 2-5. FIG. 4 is a partially-enlarged diagram of the pressing member 16 in FIG. 2. FIG. 5 is a partially-enlarged diagram of the positioning base 14 in FIG. 2. As shown in FIGS. 2-5, the pressing member 16 could be formed by a 3D printing process along a thickness direction T of the pressing member 16 and has layered marks. The positioning base 14 could be formed by stacking a plurality of layered structures 15 via a 3D printing process and has layered marks. In such a manner, through friction forces generated by contact between the layered marks of the positioning base 14 and the pressing member 16 and a lateral elastic force provided by the elastic arm 22, the hook 24 can be more firmly positioned in the engaging groove 20 (as shown in FIG. 3), so as to provide an appropriate pressure to the chip 12, thereby reliably achieving the electrical connection between the chip 12 and the test circuit board 1.

Furthermore, in this embodiment, as shown in FIG. 3, the engaging groove 20 could preferably have an inclined surface 26 and a horizontal limiting surface 28, and the horizontal limiting surface 26 could be preferably 45 degrees to the inclined surface 28 (but not limited thereto). Accordingly, the hook 24 can abut against the inclined surface 28 to be positioned in the engaging groove 20, and the horizontal limiting surface 26 can be used to stop the hook 24 to effectively prevent the hook 24 from accidentally detaching from the engaging groove 20 due to improper operation. Moreover, the present invention could further adopt an arm stop design. For example, as shown in FIGS. 2-4, each elastic arm 22 of the pressure member 16 (but not limited thereto, meaning that the present invention could adopt the design in which there is only one elastic arm having an abutment block) could protrude inward to form an abutment block 23 (preferably in a cylindrical shape). The abutment blocks 23 can abut against each other when the pressure member 16 receives an excessive lateral pressure, so as to prevent the elastic arms 22 from being excessively deformed or even broken, thereby improving the service life and operational reliability of the pressing member 16.

As for the positioning design of the test tool 10, as shown in FIGS. 1-3, the test circuit board 1 could have at least one first protruding electronic component 5 and at least one second protruding electronic component 6 (i.e., common circuit board components such as power sockets or M.2 sockets, only one shown in FIG. 1 respectively, but not limited thereto) respectively located on opposite sides of the plurality of contacts 2, and two guide slots 30 could be recessed inward from opposite sides of the positioning base 14. The test tool 10 could further include a first positioning block structure 32 and a second positioning block structure 34.

The first positioning block structure 32 has a first positioning hole structure 36, and two first positioning arms 38 respectively extend from the first positioning block structure 32 corresponding to the opposite sides of the positioning base 14. Two first ribs 40 protrude from the two first positioning arms 38 toward the two guide slots 30 respectively. Similarly, the second positioning block structure 34 has a second positioning hole structure 42, and two second positioning arms 44 respectively extend from the second positioning block structure 34 corresponding to the opposite sides of the positioning base 14. Two second ribs 46 protrude from the two second positioning arms 44 toward the two guide slots 30 respectively. The first rib 40 and the second rib 46 could be preferably a regular triangular prism structure (but not limited thereto), and the guide slot 30 could correspondingly be in a regular triangle shape to be matched with the first rib 40 and the second rib 46 for enhancing the structural engagement stability between the guide slot 30 and the first rib 40 and the second rib 46.

Via the above design, the first positioning hole structure 36 and the second positioning hole structure 42 can respectively receive the first protruding electronic component 5 and the second protruding electronic component 6, and the two first ribs 40 and the two second ribs 46 can slide into the two guide slots 30 respectively, so that the two first positioning arms 38 and the two second positioning arms 44 can clamp the positioning base 14 (as shown in FIG. 1), thereby firmly positioning the positioning base 14 on the test circuit board 1.

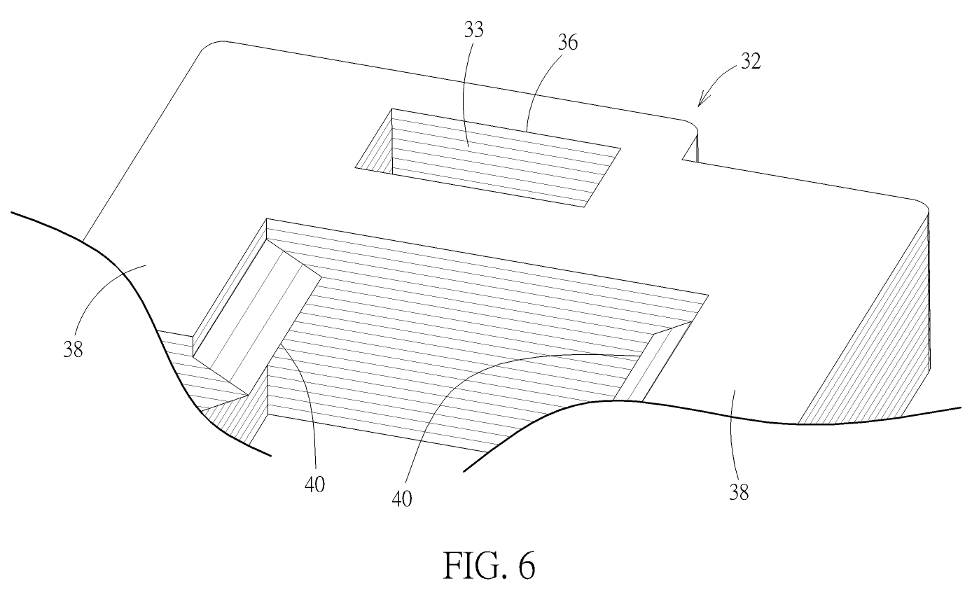

To be noted, the present invention could preferably adopt a 3D printing process to manufacture the first positioning block structure 32 and the second positioning block structure 34. More detailed description for the first positioning block structure 32 being formed by a 3D printing process is provided as follows. As for the related description for the second positioning block structure 34 being formed by a 3D printing process, it could be reasoned by analogy and omitted herein. Please refer to FIG. 1, FIG. 5 and FIG. 6. FIG. 6 is a partially-enlarged diagram of the first positioning block structure 32 in FIG. 2. As shown in FIGS. 1, 5 and 6, the first positioning block structure 32 could be formed by stacking a plurality of layered structures 33 via a 3D printing process and has layered marks, wherein a thickness of each layered structure 33 of the first positioning block structure 32 could be preferably equal to or a multiple of a thickness of each layered structure 15 of the positioning base 14 (for example, the thickness of each layered structure 33 could be equal to 0.4mm and the thickness of each layered structure 15 could be equal to 0.2mm, but not limited thereto). Thus, via the surface friction between wavy layered marks formed by the plurality of layered structures 33 and the first protruding electronic component 5, the first positioning hole structure 36 can firmly receive the first protruding electronic component 5, thereby improving the structural engagement stability between the first positioning block structure 32 and the test circuit board 1. In addition, via the contact friction between layered marks of the plurality of layered structures 15 and the plurality of layered structures 33, the guide slot 30 can be tightly matched with the first rib 40, thereby enhancing the structural engagement strength between the positioning base 14 and the first positioning block structure 32, so that the positioning base 14 can be more firmly positioned on the test circuit board 1.

In summary, the test tool provided by the present invention utilizes the positioning base to receive the probe base for making the probes of the probe base coupled to the pins of the chip and aligned with the contacts of the test circuit board. Next, after the pressing member is engaged with the hole and presses the chip downward, the chip can be electrically connected to the test circuit board via the probe base. In such a manner, via the aforesaid simple pressing operation, the electrical connection between the chip and the test circuit board can be quickly and easily completed, so as to effectively solve the prior art problem that the test tool design is too complicated to increase the tool manufacturing cost and cause difficulties in operating the test tool, thereby greatly improving the operating convenience of the test tool. In addition, via the aforesaid positioning block design, the test tool of the present invention can directly utilize the fixation between the positioning block and the protruding electronic component of the test circuit board and the concave-convex engagement between the positioning block and the positioning base to firmly position the positioning base on the test circuit board without performing any time-consuming and strenuous screw/metal-fastener fixing operations, thereby greatly reducing the chip testing time and cost.

It should be mentioned that the present invention is not limited to the double-block clamping design mentioned in the aforesaid embodiment. The present invention could also adopt a single-block limiting design to simplify the positioning block design of the test tool. Alternatively, the present invention could adopt a block splicing design to enhance the assembly flexibility of the test tool, thereby avoiding the problem that the overall positioning block structure is too large due to the protruding electronic components being too far away from the contacts.

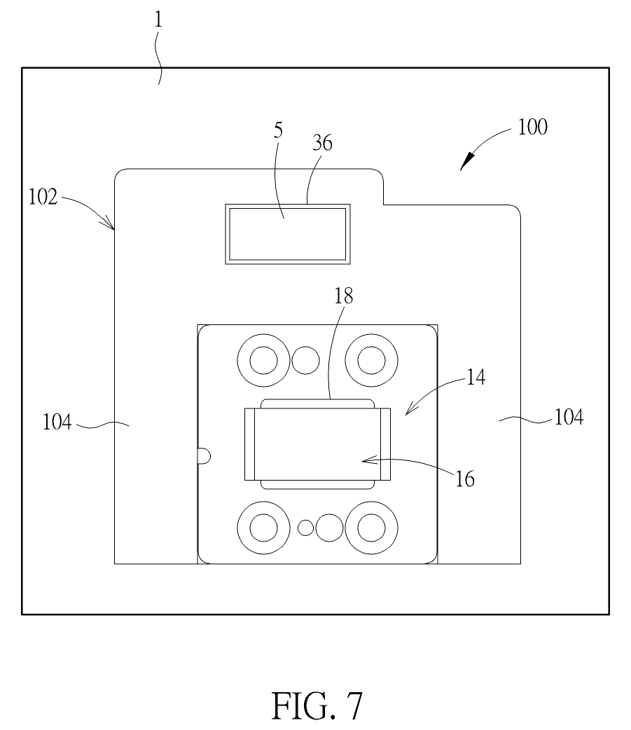

For example, please refer to FIG. 7, which is a top view of a test tool 100 mounted on the test circuit board 1 according to another embodiment of the present invention. Components both mentioned in this embodiment and the aforesaid embodiments represent components with similar structures or functions, and the related description could be reasoned by analogy according to the aforesaid embodiments and omitted herein. As shown in FIG. 7, in this embodiment, the test tool 100 includes the positioning base 14, the pressing member 16, and a first positioning block structure 102. The first positioning block structure 102 has the first positioning hole structure 36, and two first positioning arms 104 respectively extend from the first positioning block structure 102 corresponding to the opposite sides of the positioning base 14, and the two first ribs 40 respectively protrude from the two first positioning arms 104 toward the two guide slots 30 (not shown in the figure, and the related description could be reasoned by analogy according to FIG. 2).

Via the above design, the first positioning hole structure 36 can receive the first protruding electronic component 5 and the first rib 40 of each first positioning arm 104 can be slidably inserted into the corresponding guide slot 30, so that the test tool 100 can position the positioning base 14 between the two first positioning arms 104 via the first positioning block structure 102, thereby fixing the positioning base 14 on the test circuit board 1. As for other derived designs of the test tool 100 (e.g., the 3D printing process design, the engaging groove design, the thickness design, and the rib/slot design), the related description could be reasoned by analogy according to the aforesaid embodiments and omitted herein.

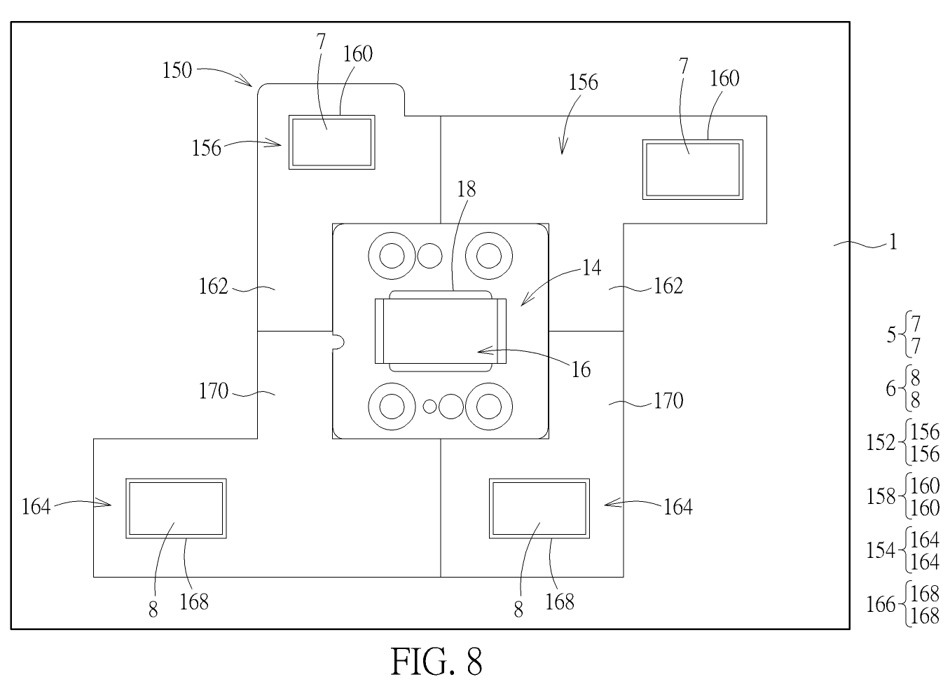

Furthermore, please refer to FIG. 8, which is a top view of a test tool 150 mounted on the test circuit board 1 according to another embodiment of the present invention. Components both mentioned in this embodiment and the aforesaid embodiments represent components with similar structures or functions, and the related description could be reasoned by analogy according to the aforesaid embodiments and omitted herein. As shown in FIG. 8, in this embodiment, the first protruding electronic component 5 includes two adjacent protruding electronic components 7, the second protruding electronic component 6 includes two adjacent protruding electronic components 8, and the test tool 150 includes the positioning base 14, the pressing member 16, a first positioning block structure 152 and a second positioning block structure 154.

The first positioning block structure 152 includes two first positioning blocks 156 and has a first positioning hole structure 158. The first positioning hole structure 158 includes two first positioning holes 160 respectively formed on the two first positioning blocks 156. Two first positioning arms 162 respectively extend from the two first positioning blocks 156. The second positioning block structure 154 includes two second positioning blocks 164 and has a second positioning hole structure 166. The second positioning hole structure 166 includes two second positioning holes 168 respectively formed on the two second positioning blocks 164. Two second positioning arms 170 respectively extend from the two second positioning blocks 164. The two first ribs 40 and the two second ribs 46 respectively protrude from the two first positioning arms 162 and the two second positioning arms 170 toward the two guide slots 30 (not shown in the figure, and the related description could be reasoned by analogy according to FIG. 2).

Via the aforesaid design, the two first positioning holes 160 can respectively receive the two adjacent protruding electronic components 7, the two second positioning holes 168 can respectively receive two adjacent protruding electronic components 8, and the first rib 40 of each first positioning arm 162 and the second rib 46 of each second positioning arm 170 can respectively slide into the corresponding guide slot 30, so that the two first positioning arms 162 and the two second positioning arms 170 can clamp the positioning base 14, thereby firmly positioning the positioning base 14 on the test circuit board 1. As for other derived designs of the test tool 150 (e.g., the 3D printing process design, the engaging groove design, the thickness design, and the rib/slot design), the related description could be reasoned by analogy according to the aforesaid embodiments and omitted herein.

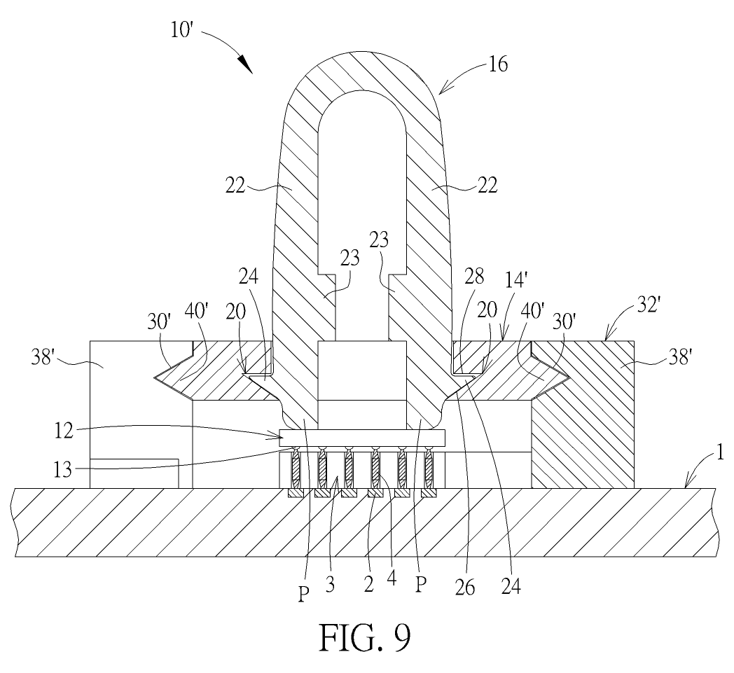

In practical applications, the structural engagement design of the positioning base and the positioning block structure of the present invention is not limited to the concave-convex engagement design shown in FIG. 3, meaning that the present invention could adopt a convex-concave engagement design in another embodiment. For example, please refer to FIG. 9, which is a cross-sectional diagram of a test tool 10' according to another embodiment of the present invention. Components both mentioned in this embodiment and the aforesaid embodiments represent components with similar structures or functions, and the related description could be reasoned by analogy according to the aforesaid embodiments and omitted herein. As shown in FIG. 9, in this embodiment, the test tool 10' includes the pressing member 16, a positioning base 14', a first positioning block structure 32' and a second positioning block structure (not shown in the figure), and two ribs 40' respectively protrude from opposite sides of the positioning base 14'.

The first positioning block structure 32' has the first positioning hole structure 36, and two first positioning arms 38' respectively extend from the first positioning block structure 32' corresponding to the opposite sides of the positioning base 14', and two guide slots 30' are respectively recessed from the two first positioning arms 38' corresponding to the two ribs 40'. Via the above design, the first positioning hole structure 36 of the first positioning block structure 32' can receive the first protruding electronic component 5 and the two ribs 40' of the positioning base 14' can slide into the two guide slots 30' of the first positioning block structure 32' respectively, so that the positioning base 14' can be positioned between the two first positioning arms 38'.

In addition, the second positioning block structure of the test tool 10' could also adopt a similar convex-concave engagement design (the related description of the second positioning hole structure, the second positioning arm, and the second guide slot could be reasoned by analogy according to FIG. 9 and omitted herein) to produce an arm positioning effect, so as to firmly position the positioning base 14' on the test circuit board 1 together with the first positioning block structure 32'. As for other derived designs of the test tool 10’ (e.g., the 3D printing process design, the engaging groove design, the thickness design, and the rib/slot design), the related descriptions could be reasoned by analogy according to the above-mentioned embodiments and omitted herein.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A test tool suitable for positioning a chip to be coupled to a test circuit board, the chip having a plurality of pins, the test circuit board having a plurality of contacts and a probe base with a plurality of probes, and the test tool comprising:
a positioning base having a hole for accommodating the chip, the positioning base being positioned on the test circuit board and receiving the probe base to make the plurality of probes contained in the hole to be connected to the plurality of pins and aligned with the plurality of contacts, and a wall of the hole forming two engaging grooves opposite to each other; and
a pressing member having two elastic arms, wherein an engaging end portion of each elastic arm forms a hook protruding toward the engaging groove and presses the chip when the pressing member is pressed into the hole to make the hook engaged with the engaging groove, for electrically connecting the plurality of pins to the plurality of contacts via the plurality of probes.

2. The test tool of claim 1, wherein the test circuit board further has at least one first protruding electronic component, two guide slots are respectively recessed inward from opposite sides of the positioning base, and the test tool further comprises:
a first positioning block structure having a first positioning hole structure, two first positioning arms respectively extending from the first positioning block structure corresponding to the opposite sides of the positioning base, and two first protruding ribs respectively protruding from the two first positioning arms toward the two guide slots;
wherein the first positioning hole structure receives the at least one first protruding electronic component and the two first protruding ribs respectively slide into the two guide slots, for accommodating the positioning base between the two first positioning arms.

3. The test tool of claim 2, wherein the at least one first protruding electronic component comprises two adjacent protruding electronic components, the first positioning block structure comprises two first blocks, the first positioning hole structure comprises two first positioning holes respectively formed on the two first positioning blocks, and the two first positioning arms respectively extend from the two first positioning blocks;
wherein the two first positioning holes respectively receive the two adjacent protruding electronic components and the two first protruding ribs respectively slide into the two guide slots, for accommodating the positioning base between the two first positioning arms.

4. The test tool of claim 2, wherein the positioning base and the first positioning block structure are respectively formed by stacking a plurality of layered structures via a 3D printing process.

5. The test tool of claim 4, wherein a thickness of each layered structure of the first positioning block structure is equal to or a multiple of a thickness of each layered structure of the positioning base.

6. The test tool of claim 5, wherein the thickness of each layered structure of the first positioning block structure is equal to 0.4mm, and the thickness of each layered structure of the positioning base is equal to 0.2mm.

7. The test tool of claim 2, wherein the first protruding rib is a regular triangular prism structure, and the guide slot is in a regular-triangle shape to be matched with the first protruding rib.

8. The test tool of claim 2, wherein the test circuit board further has at least one second protruding electronic component, the at least one first protruding electronic component and the at least one second protruding electronic component are respectively located at opposite sides of the plurality of contacts, and the test tool further comprises:
a second positioning block structure having a second positioning hole structure, two second positioning arms respectively extending from the second positioning block structure corresponding to the opposite sides of the positioning base, and two second protruding ribs respectively protruding from the two second positioning arms toward the two guide slots;
wherein the first positioning hole structure and the second positioning hole structure respectively receive the at least one first protruding electronic component and the at least one second protruding electronic component and the two first protruding ribs and the two second protruding ribs respectively slide into the two guide slots, for clamping the positioning base via the two first positioning arms and the two second positioning arms.

9. The test tool of claim 8, wherein the at least one second protruding electronic component comprises two adjacent protruding electronic components, the second positioning block structure comprises two second blocks, the second positioning hole structure comprises two second positioning holes respectively formed on the two second positioning blocks, and the two second positioning arms respectively extend from the two second positioning blocks;
wherein the two second positioning holes respectively receive the two adjacent protruding electronic components, for positioning the two second positioning blocks on the test circuit board.

10. The test tool of claim 8, wherein the positioning base, the first positioning block structure and the second positioning block structure are respectively formed by stacking a plurality of layered structures via a 3D printing process.

11. The test tool of claim 10, wherein a thickness of each layered structure of the first positioning block structure and a thickness of each layered structure of the second positioning block structure are equal to or a multiple of a thickness of each layered structure of the positioning base.

12. The test tool of claim 11, wherein the thickness of each layered structure of the first positioning block structure and the thickness of each layered structure of the second positioning block structure are equal to 0.4mm, and the thickness of each layered structure of the positioning base is equal to 0.2mm.

13. The test tool of claim 8, wherein the first protruding rib and the second protruding rib are a regular triangular prism structure, and the guide slots are in a regular-triangle shape to be matched with the first protruding rib and the second protruding rib.

14. The test tool of claim 1, wherein the pressing member is inverted-U shaped.

15. The test tool of claim 1, wherein the pressing member is formed by a 3D printing process along a thickness direction of the pressing member, and the positioning base is formed by stacking a plurality of layered structures via a 3D printing process.

16. The test tool of claim 1, wherein at least one of the two elastic arms of the pressing member protrudes inward to form an abutment block for preventing excessive deformation of the pressing member.

17. The test tool of claim 1, wherein the engaging groove has a horizontal limiting surface and an inclined surface, the horizontal limiting surface stops the hook to prevent the hook from leaving the engaging groove, and the hook abuts against the inclined surface to be positioned in the engaging groove.

18. The test tool of claim 17, wherein the horizontal limiting surface is 45 degrees to the inclined surface.

19. The test tool of claim 1, wherein the test circuit board further has at least one first protruding electronic component, two protruding ribs respectively protrude from opposite sides of the positioning base, and the test tool further comprises:
a first positioning block structure having a first positioning hole structure, two first positioning arms respectively extending from the first positioning block structure corresponding to opposite sides of the positioning base, and two first guide slots being respectively recessed from the two first positioning arms corresponding to the two protruding ribs;
wherein the first positioning hole structure receives the at least one first protruding electronic component and the two ribs respectively slide into the two first guide slots, for accommodating the positioning base between the two first positioning arms.

20. The test tool of claim 19, wherein the test circuit board further has at least one second protruding electronic component, the at least one first protruding electronic component and the at least one second protruding electronic component are respectively located at opposite sides of the plurality of contacts, and the test tool further comprises:
a second positioning block structure having a second positioning hole structure, two second positioning arms respectively extending from the second positioning block structure corresponding to opposite sides of the positioning base, and two second guide slots being respectively recessed from the two second positioning arms corresponding to the two protruding ribs;
wherein the first positioning hole structure and the second positioning block structure respectively receive the at least one first protruding electronic component and the at least one second protruding electronic component and the two ribs respectively slide into the two first guide slots and the second guide slots, for clamping the positioning base via the two first positioning arms and the second positioning arms.
